(19) United States
(12) Patent Application Publication
(10) Pub. No.: US 2026/0239978 A1
(43) Pub. Date: Aug. 13, 2026

(54) PORTABLE-SMART REFRIGERATOR WITH INTEGRATED THERMISTOR AND SEMICONDUCTOR COOLING CONTROL SYSTEM

(71) Applicant: FAIZAN AHMED, SAN JOSE, CA (US)

(72) Inventor: FAIZAN AHMED, SAN JOSE, CA (US)

(21) Appl. No.: 19/334,610

(22) Filed: Sep. 19, 2025

Related U.S. Application Data
(63) Continuation-in-part of application No. 18/772,087, filed on Jul. 12, 2024.
Application No. 18/772,087 is a continuation-in-part of application No. 18/374,646, filed on Sep. 28, 2023.
Application No. 18/374,646 is a continuation-in-part of application No. 18/205,488, filed on Jun. 2, 2023, now abandoned.
(60) Provisional application No. 63/348,484, filed on Jun. 2, 2022.

(51) Int. Cl. H10W 40/47; H10W 40/28; H10W 40/43

(52) U.S. Cl. CPC H10W 40/47; H10W 40/28; H10W 40/43

(57) ABSTRACT

In one aspect, a thermistor and Semiconductor Cooling Control System comprises a thermistor sensor configured to generate an analog signal corresponding to a temperature of at least one of a cooling compartment or a Semiconductor cooling element. The system further comprises signal conditioning circuitry configured to receive the analog signal from the thermistor sensor and suppress noise associated with high-current lines. An analog-to-digital converter input of a microcontroller is configured to digitize the conditioned signal from the signal conditioning circuitry, and control logic of the microcontroller is configured to determine a cooling requirement based on the digitized signal from the analog-to-digital converter input. A Semiconductor cooling driver is configured to receive the cooling requirement from the control logic of the microcontroller and regulate current flow, and a Semiconductor cooling element is configured to receive the regulated current flow from the Semiconductor cooling driver and provide thermoelectric cooling to the cooling compartment.

### CLAIM OF PRIORITY

This application is a continuation in part of and claims priority to U.S. patent application Ser. No. 18/772,087, filed on Sep. 28, 2023 and titled CUBOIDAL PORTABLE-SMART REFRIGERATOR METHODS AND SYSTEMS. This patent application is hereby incorporated by reference in its entirety.

U.S. patent application Ser. No. 18/772,087 is a continuation in part of and claims priority to U.S. patent application Ser. No. 18/374,646, filed on Sep. 28, 2023 and titled THERMO-ELECTRIC SYSTEM COMPRISING CHAIN TRAPEZOID ELEMENTS WITH INCREASED FIGURE OF MERIT. This patent application is hereby incorporated by reference in its entirety.

U.S. patent application Ser. No. 18/374,646 is a continuation in part of and claim priority to U.S. patent application Ser. No. 18/205,488, filed on Jun. 2, 2023 and titled PORTABLE-SMART REFRIGERATOR METHODS AND SYSTEMS.

U.S. patent application Ser. No. 18/205,488 claims priority to and incorporates by reference in its entirety U.S. application No. 63/348,484 and filed on 2 Jun. 2022 and PORTABLE-SMART REFRIGERATOR METHODS AND SYSTEMS. This patent application is hereby incorporated by reference in its entirety.

These applications are hereby incorporated by reference in their entirety.

### BACKGROUND

### Field of the Invention

The present invention relates generally to portable refrigeration systems, and more particularly to a cuboidal portable refrigerator incorporating a Thermistor and Semiconductor Cooling Control System with integrated power management and dual-mode Wireless communication.

### Description of the Related Art

Portable refrigeration devices are widely used in applications ranging from personal food storage to medical cold-chain transport. Conventional portable refrigerators typically employ compressor-based systems, simple thermoelectric coolers, or passive insulation with ice packs. These solutions often suffer from limitations such as bulky form factors, excessive power consumption, inadequate temperature stability, or lack of intelligent monitoring.

Thermoelectric (Semiconductor cooling) modules have been adopted in some compact refrigeration designs because they enable solid-state cooling without moving parts. However, Semiconductor cooling-based systems are highly sensitive to control instability, power fluctuations, and environmental conditions. Traditional implementations often rely on simple on/off control loops, resulting in inefficient operation, temperature overshoot, or battery drain.

In addition, portable refrigerators are increasingly required to operate in environments where connectivity and power flexibility are critical. Many conventional designs do not provide integrated Wireless communication, making it difficult to monitor temperature or battery status remotely. Similarly, power subsystems in existing products often lack multi-rail regulation, leading to ripple or voltage sag when high-current bursts are drawn by thermoelectric elements. These deficiencies can disrupt sensitive electronics, shorten battery life, and compromise cooling performance.

Accordingly, there remains a need for a portable refrigerator that combines precise thermistor-based sensing, resilient Semiconductor cooling actuation, efficient multi-rail power management, and integrated short-and long-range Wireless communication. The disclosed cuboidal portable-smart refrigerator addresses these shortcomings by incorporating a Thermistor and Semiconductor cooling Control System, adaptive control logic, multi-source power regulation, and coordinated communication subsystems.

### BRIEF SUMMARY OF THE INVENTION

In one aspect, a thermistor and Semiconductor Cooling Control System comprises a thermistor sensor configured to generate an analog signal corresponding to a temperature of at least one of a cooling compartment or a Semiconductor cooling element. The system further comprises signal conditioning circuitry configured to receive the analog signal from the thermistor sensor and suppress noise associated with high-current lines. An analog-to-digital converter input of a microcontroller is configured to digitize the conditioned signal from the signal conditioning circuitry, and control logic of the microcontroller is configured to determine a cooling requirement based on the digitized signal from the analog-to-digital converter input. A Semiconductor cooling driver is configured to receive the cooling requirement from the control logic of the microcontroller and regulate current flow, and a Semiconductor cooling element is configured to receive the regulated current flow from the Semiconductor cooling driver and provide thermoelectric cooling to the cooling compartment.

### BRIEF DESCRIPTION OF THE DRAWINGS

FIG. 1 illustrates a Thermistor and Semiconductor cooling Control System according to some embodiments.

FIG. 2 illustrates a System Architecture according to some embodiments. System Architecture integrates Thermistor and Semiconductor cooling Control System with additional control, communication, and power management elements to provide a complete portable refrigeration platform, according to some embodiments.

FIG. 3 illustrates a system-level organization of a board, serving as a functional map before the detailed circuits are presented on later pages, according to some embodiments.

FIG. 4 illustrates a Process for Thermistor and Semiconductor cooling Control System, according to some embodiments.

FIG. 5 illustrates Integration of Process 400 into a System Architecture, according to some embodiments.

FIG. 6 illustrates Process for integration of Thermistor and Semiconductor cooling Control System 100 with power and communications subsystems.

FIG. 7 illustrates an exploded view of a cuboidal portable-smart refrigerator according to some embodiments.

The Figures described above are a representative set and are not an exhaustive with respect to embodying the invention.

### DESCRIPTION

Disclosed are a system, method, and article of manufacture for a portable-smart refrigerator with integrated thermistor and Semiconductor Cooling Control System. The following description is presented to enable a person of ordinary skill in the art to make and use the various embodiments. Descriptions of specific devices, techniques, and applications are provided only as examples. Various modifications to the examples described herein can be readily apparent to those of ordinary skill in the art, and the general principles defined herein may be applied to other examples and applications without departing from the spirit and scope of the various embodiments.

Reference throughout this specification to ‘one embodiment,’ ‘an embodiment,’ ‘one example,’ or similar language means that a particular feature, structure, or characteristic described in connection with the embodiment is included in at least one embodiment, according to some embodiments. Thus, appearances of the phrases ‘in one embodiment,’ ‘in an embodiment,’ and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of embodiments of the invention. One skilled in the relevant art can recognize, however, that the invention may be practiced without one or more of the specific details, or with other methods, components, materials, and so forth. In other instances, well-known structures, materials, or operations are not shown or described in detail to avoid obscuring aspects of the invention.

The schematic flow chart diagrams included herein are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, and they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

Definitions

Example definitions for some embodiments are now provided.

Acrylonitrile butadiene styrene (ABS) is a common plastic polymer.

High-density polyethylene (HDPE) or polyethylene high-density (PEHD) is a polyethylene thermoplastic made from petroleum.

Semiconductor cooling effect is the presence of heating or cooling at an electrified junction of two different conductors. When a current is made to flow through a junction between two conductors, A and B, heat may be generated or removed at the junction. Thermoelectric cooling uses the Semiconductor cooling effect to create a heat flux between the junction of two different types of materials. A Semiconductor cooling cooler, heater, or thermoelectric heat pump is a solid-state active heat pump which transfers heat from one side of the device to the other, with consumption of electrical energy, depending on the direction of the current.

Thermal-chemical is a substance with a high heat of fusion which, melting and solidifying at a certain temperature, is capable of storing and releasing large amounts of energy. Heat is absorbed or released when the material changes from solid to liquid and vice versa.

Polypropylene (PP) is a thermoplastic polymer used in a wide variety of applications. It is produced via chain-growth polymerization from the monomer propylene.

Press fit or friction fit is a fastening between two parts which is achieved by friction after the parts are pushed together, rather than by any other means of fastening.

Temperature sensors can include mechanical temperature sensors, electrical temperature sensors, integrated circuit sensors, thermometers, etc.

Thermoelectric effect is the direct conversion of temperature differences to electric voltage and vice versa via a thermocouple. A thermoelectric device creates voltage when there is a different temperature on each side. Conversely, when a voltage is applied to it, heat is transferred from one side to the other, creating a temperature difference. At the atomic scale, an applied temperature gradient causes charge carriers in the material to diffuse from the hot side to the cold side.

### Example Systems and Methods

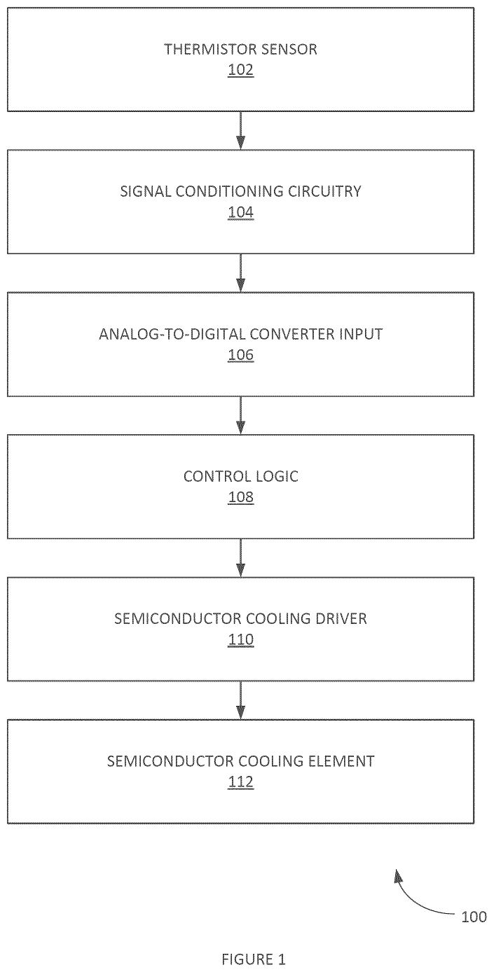

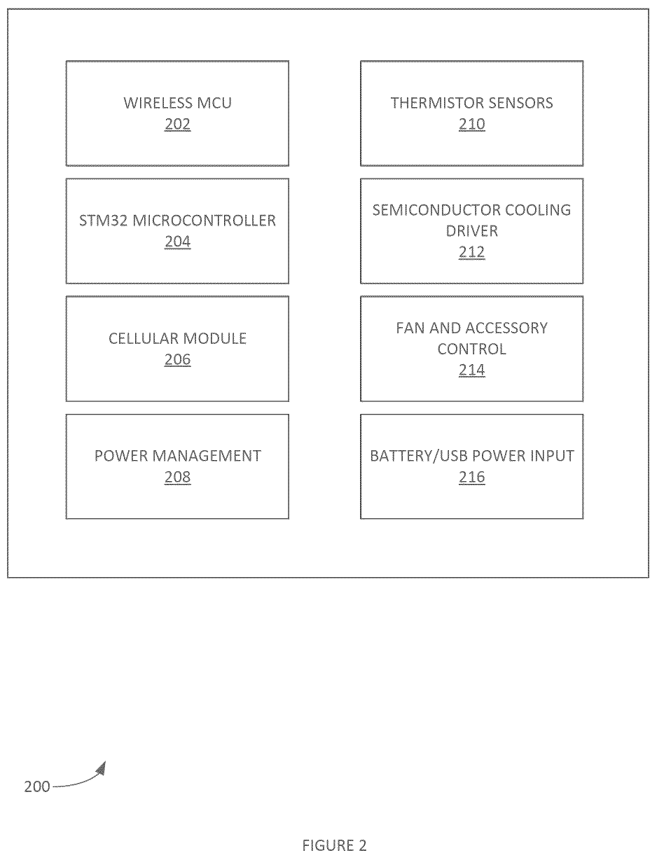

FIG. 1 illustrates a Thermistor and Semiconductor cooling Control System 100 according to some embodiments. Thermistor and Semiconductor cooling Control System 100 implements a closed-loop feedback architecture in which temperature is continuously sensed, conditioned, digitized, evaluated, and regulated by actuation of a thermoelectric element. Thermistor and Semiconductor cooling Control System 100 further coordinates with power regulation, communication, and safety circuits described in FIG. 2 to enable robust operation in a compact, battery-powered refrigerator.

Thermistor and Semiconductor cooling Control System 100 includes a Thermistor Sensor 102 configured to monitor temperature within the cooling compartment and/or directly on a Semiconductor Cooling Element 112. The Thermistor Sensor 102 may be bonded to a surface using a thermally conductive adhesive or placed in an airstream to provide rapid response to compartment fluctuations. In some embodiments, multiple Thermistor Sensors 102 are employed, including dedicated ADC inputs such as ADC_TH for compartment monitoring and ADC_SCE (Semiconductor Cooling Element) for Semiconductor Cooling Element 112 surface monitoring. This configuration enables Thermistor and Semiconductor cooling Control System 100 to distinguish between environmental load changes and self-heating of Semiconductor Cooling Element 112. Accurate sensing from Thermistor Sensor 102 prevents overshoot and wasted energy, which is critical for small portable refrigerators with low thermal mass.

Thermistor and Semiconductor cooling Control System 100 transmits the analog signal from Thermistor Sensor 102 to Signal Conditioning Circuitry 104. Signal Conditioning Circuitry 104 may include biasing networks, operational amplifier buffers, and RC filters tuned to suppress high-frequency interference while preserving the thermal bandwidth of interest. Signal Conditioning Circuitry 104 isolates noisy, high-current lines associated with Semiconductor Cooling Driver 110 from low-level analog inputs, thereby improving accuracy. In some embodiments, Signal Conditioning Circuitry 104 is optimized to reject switching transients from Semiconductor Cooling Driver 110 while also preventing radio-frequency interference from Wireless MCU 202 and Cellular Module 206.

The conditioned signal from Signal Conditioning Circuitry 104 is then provided to an Analog-to-Digital Converter Input 106 of STM32 Microcontroller 204. Analog-to-Digital Converter Input 106 samples the temperature signal at selectable resolutions, for example 10-bit or 12-bit, and may employ oversampling to increase effective resolution. Analog-to-Digital Converter Input 106 may be synchronized with PWM cycles generated by Semiconductor Cooling Driver 110 to minimize measurement noise. Integration of Analog-to-Digital Converter Input 106 with STM32 Microcontroller 204 ensures direct firmware access to real-time thermal data.

The STM32 Microcontroller 204 executes Control Logic 108, which evaluates data from Analog-to-Digital Converter Input 106 and determines actuation requirements for Semiconductor Cooling Driver 110. Control Logic 108 may implement proportional-integral-derivative (PID) algorithms, hysteresis thresholds, or adaptive gain control to maintain stability. Control Logic 108 may also arbitrate between cooling demand and available power, adjusting duty cycles of Semiconductor Cooling Driver 110 when Cellular Module 206 is transmitting to prevent supply droop. Control Logic 108 further synchronizes cooling activity with Power Management 208, enabling efficient balancing of performance and battery longevity.

Based on decisions from Control Logic 108, Semiconductor Cooling Driver 110 regulates electrical current through Semiconductor Cooling Element 112. Semiconductor Cooling Driver 110 may implement pulse-width modulation with current limiting to protect Semiconductor Cooling Element 112 from inrush currents. Semiconductor Cooling Driver 110 is designed to maintain stability under high-current bursts that are characteristic of thermoelectric devices. In some embodiments, Semiconductor Cooling Driver 110 includes coatings or encapsulations to resist condensation or mechanical vibration, thereby ensuring reliability in portable use.

Semiconductor Cooling Element 112 is positioned to provide thermoelectric cooling when forward-biased. Semiconductor Cooling Element 112 is mounted so that its cold side interfaces with the cooling compartment, while its hot side is coupled to a heatsink and fan assembly. Thermistor and Semiconductor Cooling Control System 100 adjusts current through Semiconductor Cooling Element 112 based on measurements from Thermistor Sensor 102, thereby ensuring that the cold side temperature is regulated with minimal overshoot. By dynamically coordinating the actuation of Semiconductor Cooling Element 112 with input from multiple Thermistor Sensors 102, Thermistor and Semiconductor cooling Control System 100 maintains stable compartment conditions under fluctuating loads.

Thermistor and Semiconductor cooling Control System 100 also interfaces with Power Management 208 of FIG. 2. Power Management 208 generates multiple voltage rails (for example 1.2 V, 1.4 V, 1.8 V, 3.3 V, and 5 V Cellular Module 206 V) to operate STM32 Microcontroller 204, Wireless MCU 202, Cellular Module 206, Analog-to-Digital Converter Input 106, and Semiconductor Cooling Driver 110 at their most efficient voltages. Power Management 208 is optimized to minimize quiescent current, thereby reducing idle drain and extending battery life. Clean regulation from Power Management 208 ensures that high-current bursts demanded by Semiconductor Cooling Driver 110 do not induce voltage sag or ripple that would otherwise disrupt Wireless MCU 202, Cellular Module 206, or Analog-to-Digital Converter Input 106.

Thermistor and Semiconductor cooling Control System 100 is further linked with Wireless MCU 202 and Cellular Module 206 of FIG. 2. Wireless MCU 202 provides local connectivity to nearby smartphones, while Cellular Module 206 enables remote telemetry for fleet monitoring or medical applications. Control Logic 108 within STM32 Microcontroller 204 coordinates with Wireless MCU 202 and CELLULAR (e.g. LTE, etc.) MODULE 206 to transmit compartment temperature, battery status, and operating mode. Integration of Wireless MCU 202 and Cellular Module 206 with Thermistor and Semiconductor cooling Control System 100 allows both short-range and long-range monitoring, which is novel in compact refrigeration appliances.

Thermistor and Semiconductor cooling Control System 100 also interacts with Safety and Reliability Circuits described in FIG. 2. These include charge-enable lines, boost-enable controls, and decoupling networks that protect against deep discharge and irregular power transitions. By coordinating with Power Management 208, Thermistor and Semiconductor cooling Control System 100 ensures smooth startup when switching between Battery/USB Power Input 216 and battery operation. Safety circuits enable Thermistor and Semiconductor cooling Control System 100 to maintain consistent performance even when subjected to irregular charging sources, such as vehicle adapters or solar inputs.

Collectively, Thermistor Sensor 102, Signal Conditioning Circuitry 104, Analog-to-Digital Converter Input 106, Control Logic 108 of STM32 Microcontroller 204, Semiconductor Cooling Driver 110, and Semiconductor Cooling Element 112, in conjunction with Power Management 208, Wireless MCU 202, Cellular Module 206, and safety subsystems, define Thermistor and Semiconductor cooling Control System 100. The architecture of Thermistor and Semiconductor cooling Control System 100 enables precise, efficient, and reliable cooling control in a compact portable refrigerator, distinguishing it from conventional desktop or household refrigeration systems.

FIG. 2 illustrates a System Architecture 200 according to some embodiments. System Architecture 200 integrates Thermistor and Semiconductor cooling Control System 100 with additional control, communication, and power management elements to provide a complete portable refrigeration platform, according to some embodiments. System Architecture 200 includes Wireless MCU 202, which may be a Dialog DA14681 system-on-chip with integrated RF front-end and chip antenna. Wireless MCU 202 provides short-range Wireless connectivity for local device control via smartphones or tablets. Wireless MCU 202 is configured to receive compartment temperature values and battery status from STM32 Microcontroller 204 and to relay these parameters Wirelessly to a user interface application.

System Architecture 200 further includes STM32 Microcontroller 204, which serves as the central processing and arbitration unit. STM32 Microcontroller 204 executes Control Logic 108 of Thermistor and Semiconductor cooling Control System 100 and coordinates with Wireless MCU 202 and Cellular Module 206. STM32 Microcontroller 204 manages PWM outputs to Semiconductor Cooling Driver 110, processes ADC inputs from Thermistor Sensor 102, and balances current consumption relative to available power from Power Management 208.

Cellular Module 206, which may be a Quectel BG95 (by way of example), is included in System Architecture 200 to provide long-range communication. Cellular Module 206 enables transmission of telemetry data such as compartment temperature, battery voltage, and runtime history to remote servers for fleet monitoring or medical transport applications. Cellular Module 206 integrates with STM32 Microcontroller 204 over serial or USB interfaces to synchronize communication tasks with cooling cycles, reducing power draw during active radio transmission.

System Architecture 200 includes Power Management 208, which generates regulated rails of 1.2 V, 1.4 V, 1.8 V, 3.3 V, and 5 V. Power Management 208 supplies STM32 Microcontroller 204, Wireless MCU 202, Cellular Module 206, Analog-to-Digital Converter Input 106, and Semiconductor Cooling Driver 110 with stable operating voltages. Power Management 208 is optimized for low quiescent current draw, thereby minimizing idle battery drain and maintaining efficiency during high-current Semiconductor cooling actuation.

System Architecture 200 includes Thermistor Sensors 210 connected through Signal Conditioning Circuitry 104 to STM32 Microcontroller 204. Thermistor Sensors 210 provide continuous monitoring of compartment and Semiconductor cooling element temperature, enabling fine-grained feedback control.

System Architecture 200 includes Semiconductor cooling Driver 212, which regulates current flow to Semiconductor Cooling Element 112 under command from STM32 Microcontroller 204. Semiconductor cooling Driver 212 maintains operation under dynamic current loads while preserving stability in the presence of Wireless transmissions from Wireless MCU 202 and Cellular Module 206.

System Architecture 200 includes Fan and Accessory Control 214, which operates cooling fans or optional actuators that dissipate heat from the hot side of Semiconductor Cooling Element 112. Fan and Accessory Control 214 coordinates with STM32 Microcontroller 204 to dynamically modulate airflow depending on sensed temperatures and cooling demand.

System Architecture 200 further includes Battery/USB Power Input 216, which accepts external USB input or battery supply. Battery/USB Power Input 216 coordinates with Power Management 208 to provide seamless handoff between input sources. In portable refrigeration use, Battery/USB Power Input 216 ensures consistent operation even under irregular charging conditions.

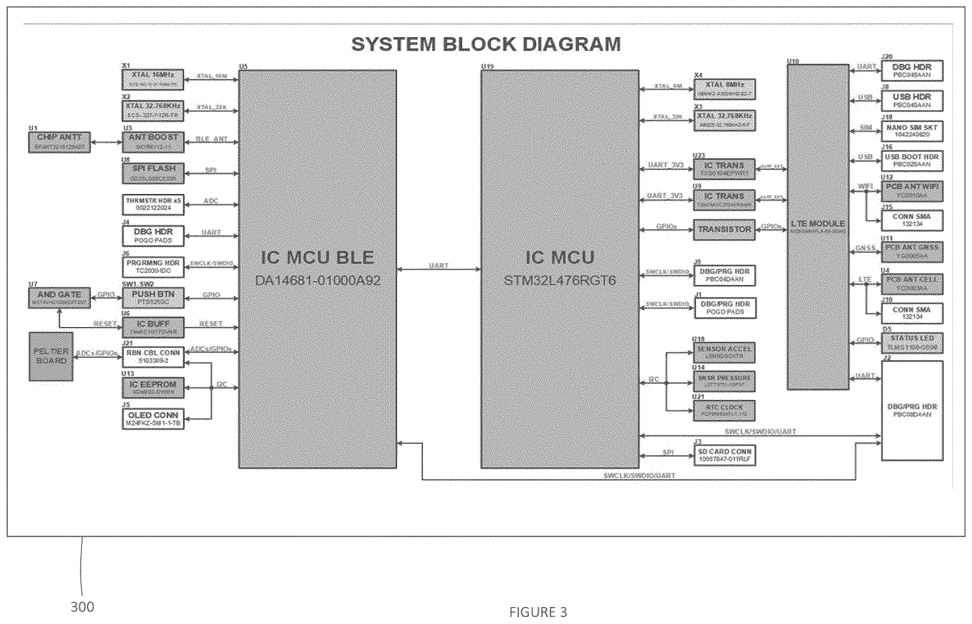

FIG. 3 illustrates a system-level organization of a board 300, serving as a functional map before the detailed circuits are presented on later pages, according to some embodiments. The MCU BLE subsystem is presented as a core building block, using the Dialog DA14681 Bluetooth system-on-chip. This subsystem interfaces with external crystals, SPI buses, I²C interfaces, and an RF front-end tied to the antenna. Multiple regulated supply rails are called out for the MCU BLE subsystem, including 3.3 V at 100 mA, 1.8 V at 75 mA, 1.4 V at 20 mA, and 1.2 V at 50 mA, showing that the design is optimized for energy efficiency by distributing power in fine-grained domains.

The block diagram illustrates connections between the MCU BLE subsystem and other functional units. I²C_SCL and I²C_SDA lines support communication with shared peripherals, QSPI links support external flash memory, and ADC_TH pins connect directly to thermistors. These connections demonstrate the system's capacity to sense both environmental and component-level temperatures with dedicated accuracy. Reset buffers and debugging headers are also present, reinforcing that the architecture was designed for both development and maintainability.

The STM32 microcontroller block is highlighted separately. The STM32 coordinates analog-to-digital conversion from the thermistor inputs, manages PWM outputs to the Semiconductor cooling driver, and arbitrates activity between radios and the cooling loop. The LTE module is also represented, with its full circuitry shown on other schematic pages, but included here to illustrate system interconnects. Together with the MCU BLE subsystem, these communication modules are tied into the STM32 through serial and control lines, enabling both short-range and long-range telemetry.

The block diagram also includes the power management system, which distributes regulated rails derived from VBAT_MCU and VBUS_BLE inputs. These rails are central to maintaining stability during high current bursts, such as those generated by the Semiconductor cooling element when cooling demand peaks. Notes within the block diagram remind the designer to keep RF front-end and power conditioning elements carefully laid out, minimizing ripple and ensuring reliable radio performance.

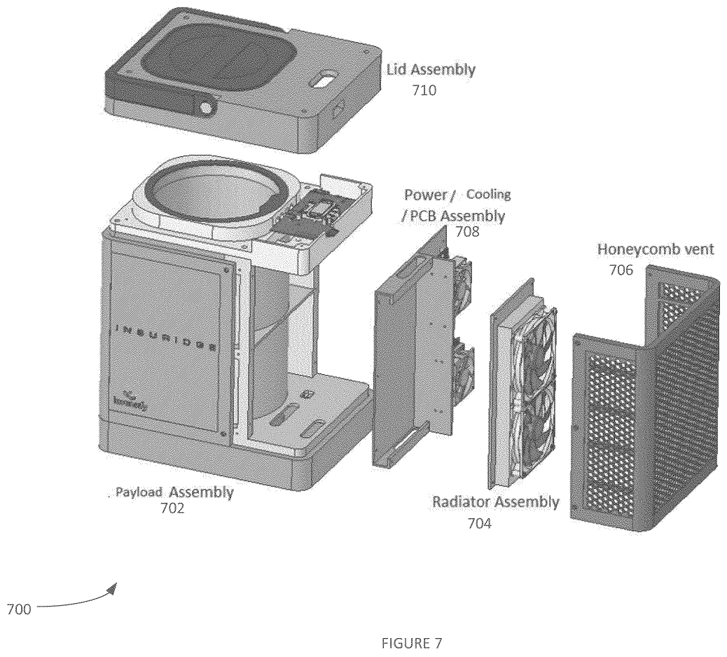

When tied to the cuboidal portable-smart refrigerator described in FIG. 7, the contents of Page 2 directly map to the cooling/PCB assembly. The ADC_TH pins, sourced from thermistors, correspond to Thermistor Sensor 102 mounted both inside the payload compartment and on the Semiconductor Cooling Element 112. These signals are conditioned and digitized before being evaluated by Control Logic 108 of STM32 Microcontroller 204. The PWM signals generated by the STM32 microcontroller then drive the Semiconductor Cooling Driver 110, which powers the Semiconductor Cooling Element 112 integrated into the cooling/PCB assembly 708. By placing the thermistor sensing, signal conditioning, STM32 coordination, BLE and LTE modules, and power management circuits together on the motherboard of the cooling/PCB assembly, the system forms the core intelligence of the refrigerator. This integration ensures that thermal control loops (Process 400) and their coordination with power management and communication subsystems (Process 600) are not abstracted separately, but physically embedded into the cooling/PCB assembly 708 that sits adjacent to payload assembly 702.

Cooling/PCB assembly 708 also incorporates the interconnections shown in the block diagram of Page 2, including ADC_TH lines from Thermistor Sensor 102 routed through Signal Conditioning Circuitry 104 to Analog-to-Digital Converter Input 106 of STM32 Microcontroller 204, PWM outputs from STM32 Microcontroller 204 to Semiconductor Cooling Driver 110, I²C_SCL and I²C_SDA buses linking STM32 Microcontroller 204 to Wireless MCU 202, UART control lines between STM32 Microcontroller 204 and Cellular Module 206, and SPI connections to external memory for configuration storage. Power Management 208 located within Cooling/PCB assembly 708 supplies regulated rails of 1.2 V, 1.4 V, 1.8 V, 3.3 V, and 5 V to these subsystems, while Safety Circuits manage startup and transitions between Battery/USB Power Input 216 and external sources. Fan and Accessory Control 214 driven by STM32 Microcontroller 204 regulates airflow across Radiator Assembly 704 and Honeycomb Vent 706. Together these connections integrate Thermistor and Semiconductor cooling Control System 100 with power management and dual-radio communications, ensuring that cuboidal portable-smart refrigerator 700 maintains stable cooling while providing both local and remote telemetry.

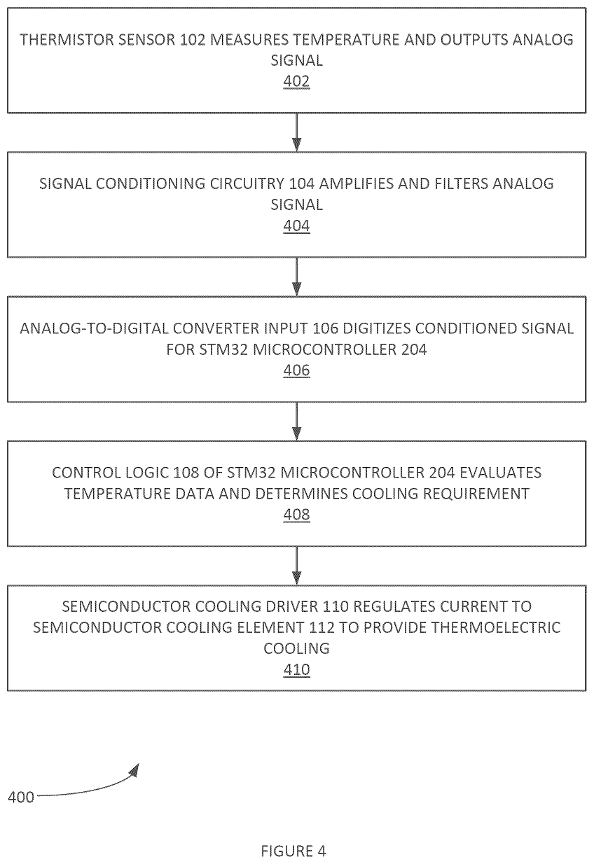

FIG. 4 illustrates a Process 400 for Thermistor and Semiconductor cooling Control System 100, according to some embodiments. At step 402, Thermistor Sensor 102 measures compartment and/or Semiconductor Cooling Element 112 surface temperature. Thermistor Sensor 102 produces an analog voltage in proportion to measured resistance and delivers this signal to Signal Conditioning Circuitry 104.

At step 404, Signal Conditioning Circuitry 104 amplifies and filters the thermistor signal. Signal Conditioning Circuitry 104 provides noise suppression from high-current bursts of Semiconductor Cooling Driver 110 and interference from Wireless MCU 202 and Cellular Module 206.

At step 406, Analog-to-Digital Converter Input 106 of STM32 Microcontroller 204 digitizes the conditioned signal. Analog-to-Digital Converter Input 106 synchronizes with PWM cycles of Semiconductor Cooling Driver 110 to minimize sampling errors and provides high-resolution thermal data.

At step 408, Control Logic 108 within STM32 Microcontroller 204 evaluates the digitized temperature data. Control Logic 108 selects actuation values for Semiconductor Cooling Driver 110 based on comparisons with desired setpoints and available power conditions from Power Management 208.

At step 410, Semiconductor Cooling Driver 110 applies regulated current to Semiconductor Cooling Element 112. Semiconductor Cooling Element 112 transfers heat via thermoelectric conduction, thereby adjusting compartment temperature.

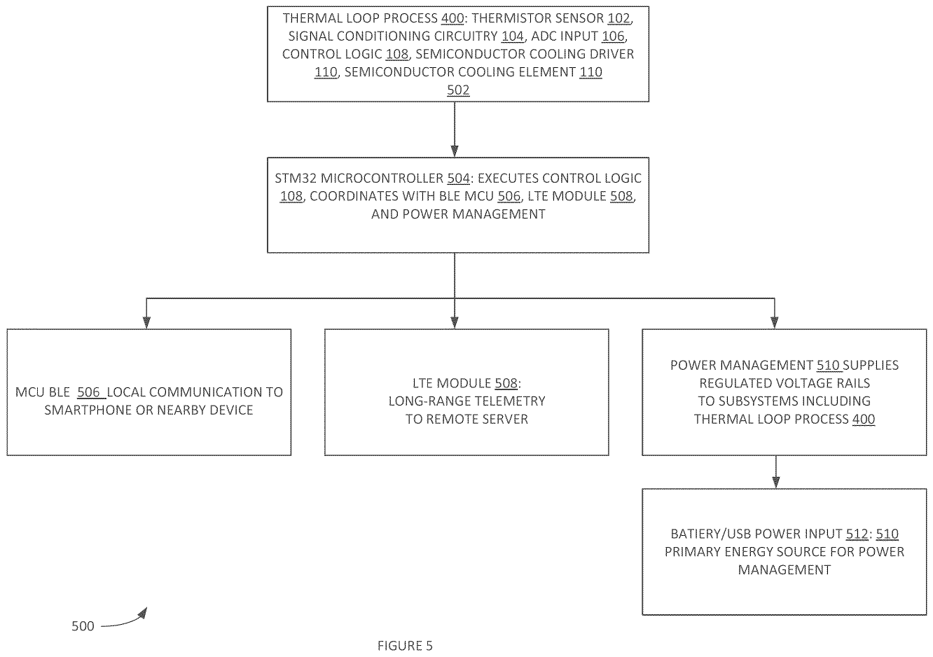

FIG. 5 illustrates Integration 500 of Process 400 into System Architecture 200, according to some embodiments. Thermal Loop Process 400 is represented as a subsystem block 502 within FIG. 5. Thermal Loop Process 400 includes Thermistor Sensor 102, Signal Conditioning Circuitry 104, Analog-to-Digital Converter Input 106, Control Logic 108, Semiconductor Cooling Driver 110, and Semiconductor Cooling Element 112.

STM32 Microcontroller 504 executes Control Logic 108 of Thermal Loop Process 400 and manages communication with MCU BLE 506 and LTE Module 508. STM32 Microcontroller 504 further coordinates with Power Management 510 to balance available energy with cooling demand.

MCU BLE 506 provides local short-range connectivity for Thermal Loop Process 400 outputs such as compartment temperature. MCU BLE 506 transmits data to smartphones or local devices.

LTE Module 508 provides long-range connectivity for remote telemetry and fleet monitoring. LTE Module 508 transmits thermal status, power status, and runtime data.

Power Management 510 provides regulated voltage rails to Thermal Loop Process 400. Power Management 510 ensures stability of Analog-to-Digital Converter Input 106 and Semiconductor Cooling Driver 110 during high-current transients.

Battery/USB Power Input 512 provides primary energy to Power Management 510. Battery/USB Power Input 512 enables continuous operation of Thermal Loop Process 400 during charging or mobile battery use.

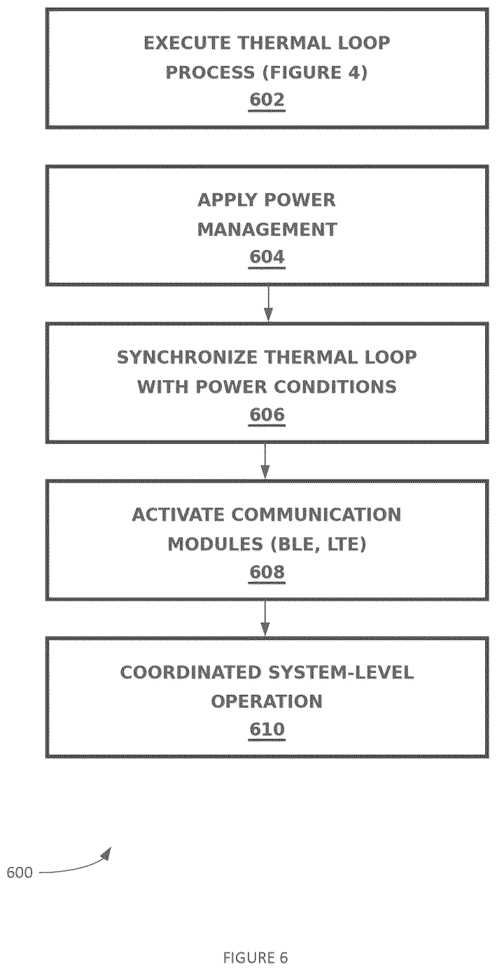

FIG. 6 illustrates Process 600 for integration of Thermistor and Semiconductor cooling Control System 100 with power and communications subsystems. At step 602, Thermistor and Semiconductor cooling Control System 100 executes Process 400 to sense, condition, digitize, and control thermal data. Semiconductor Cooling Driver 110 actuates Semiconductor Cooling Element 112 in accordance with Control Logic 108 of STM32 Microcontroller 204.

At step 604, Power Management 208 regulates input energy from Battery/USB Power Input 216. Power Management 208 ensures stable rails for STM32 Microcontroller 204, Wireless MCU 202, Cellular Module 206, and Semiconductor Cooling Driver 110.

At step 606, STM32 Microcontroller 204 synchronizes Thermistor and Semiconductor cooling Control System 100 operation with available power conditions. STM32 Microcontroller 204 may reduce duty cycle of Semiconductor Cooling Driver 110 or modulate fan operation from Fan and Accessory Control 214 to preserve battery longevity.

At step 608, Wireless MCU 202 and Cellular Module 206 are activated to transmit thermal data. Wireless MCU 202 provides local device status while Cellular Module 206 enables remote communication for monitoring and alarms.

At step 610, coordinated operation is achieved across Thermistor and Semiconductor cooling Control System 100, Power Management 208, Wireless MCU 202, and Cellular Module 206. This integration allows the portable refrigerator to dynamically balance cooling, power, and communication requirements.

### Cuboidal Portable-Smart Refrigerator

FIG. 7 illustrates an exploded view of a cuboidal portable-smart refrigerator 700 according to some embodiments. Cuboidal portable-smart refrigerator 700 includes, inter alia, a payload assembly 702, a radiator assembly 704, a cooling/PCB assembly 708, a lid assembly 710, and a honeycomb vent 706. Payload assembly 702 defines a temperature-controlled compartment for storing sensitive items such as food or medicine. Payload assembly 702 may further include structural insulation layers and reflective coatings to reduce thermal leakage, thereby lowering the load on Semiconductor Cooling Element 112 of Thermistor and Semiconductor cooling Control System 100.

Cooling/PCB assembly 708 is located adjacent to payload assembly 702 and is configured to regulate compartment temperature. Cooling/PCB assembly 708 incorporates Thermistor and Semiconductor cooling Control System 100 of FIG. 1, including Thermistor Sensor 102, Signal Conditioning Circuitry 104, Analog-to-Digital Converter Input 106, Control Logic 108 of STM32 Microcontroller 204, Semiconductor Cooling Driver 110, and Semiconductor Cooling Element 112. Semiconductor Cooling Element 112 interfaces thermally with payload assembly 702 to provide active cooling, while Thermistor Sensor 102 is mounted both within payload assembly 702 and on Semiconductor Cooling Element 112 surfaces to ensure stable feedback control. Signal Conditioning Circuitry 104, Analog-to-Digital Converter Input 106, and Control Logic 108 are implemented on the motherboard of cooling/PCB assembly 708, enabling direct communication with Wireless MCU 202 and Cellular Module 206 of FIG. 2.

Radiator assembly 704 is thermally coupled to the hot side of Semiconductor Cooling Element 112. Radiator assembly 704 may include finned heat sinks, fans under Fan and Accessory Control 214, and optional liquid-cooled components. Fan and Accessory Control 214, commanded by STM32 Microcontroller 204, adjusts airflow through radiator assembly 704 in response to sensed thermal load. Radiator assembly 704 is vented through honeycomb vent 706, which provides mechanical protection while enabling convective airflow.

Power Management 208 and Battery/USB Power Input 216 of FIG. 2 are integrated into cooling/PCB assembly 708. These circuits provide regulated rails of 1.2 V, 1.4 V, 1.8 V, 3.3 V, and 5 V to operate STM32 Microcontroller 204, Wireless MCU 202, Cellular Module 206, Thermistor and Semiconductor cooling Control System 100, and Semiconductor Cooling Driver 110. Power Management 208 ensures stability under burst current demands from Semiconductor Cooling Driver 110 while minimizing quiescent drain during idle states. Safety circuits located within cooling/PCB assembly 708 prevent overcharge, deep discharge, and unsafe transitions between wall power, car adapter input, or solar charging sources.

Wireless MCU 202 and Cellular Module 206 of FIG. 2 are also mounted on cooling/PCB assembly 708. Wireless MCU 202 provides short-range control of cuboidal portable-smart refrigerator 700 via a smartphone or tablet, while Cellular Module 206 enables remote telemetry for long-distance monitoring. In some embodiments, Wireless MCU 202 and Cellular Module 206 transmit compartment temperature, battery voltage, and runtime history generated by STM32 Microcontroller 204 executing Process 400 of FIG. 4 and Process 600 of FIG. 6. Integration of Wireless MCU 202 and Cellular Module 206 into cooling/PCB assembly 708 enables coordinated operation across thermal regulation, power management, and communication systems.

Lid assembly 710 provides mechanical access to payload assembly 702 for placement or retrieval of temperature-sensitive items. In some embodiments, Lid assembly 710 includes user interface controls coupled to STM32 Microcontroller 204 for setpoint adjustment or status indication.

In operation, cuboidal portable-smart refrigerator 700 executes Process 400 of FIG. 4 to implement Thermistor and Semiconductor cooling Control System 100, and Process 600 of FIG. 6 to integrate thermal regulation with Power Management 208, Wireless MCU 202, and Cellular Module 206. The coordinated functions across payload assembly 702, radiator assembly 704, cooling/PCB assembly 708, and lid assembly 710 enable stable temperature regulation in a compact and portable package.

### Conclusion

Although the present embodiments have been described with reference to specific example embodiments, various modifications and changes can be made to these embodiments without departing from the broader spirit and scope of the various embodiments. For example, the various devices, modules, etc. described herein can be enabled and operated using hardware circuitry, firmware, software or any combination of hardware, firmware, and software (e.g., embodied in a machine-readable medium).

In addition, it can be appreciated that the various operations, processes, and methods disclosed herein can be embodied in a machine-readable medium and/or a machine accessible medium compatible with a data processing system (e.g., a computer system), and can be performed in any order (e.g., including using means for achieving the various operations). Accordingly, the specification and drawings are to be regarded in an illustrative rather than a restrictive sense. In some embodiments, the machine-readable medium can be a non-transitory form of machine-readable medium.

1. A Thermistor and Semiconductor Cooling Control System comprising:
a thermistor sensor configured to generate an analog signal corresponding to a temperature of at least one of a cooling compartment or a Semiconductor cooling element;
signal conditioning circuitry configured to receive the analog signal from the thermistor sensor and suppress noise associated with high-current lines;
an analog-to-digital converter input of a microcontroller configured to digitize the conditioned signal from the signal conditioning circuitry;
a control logic of the microcontroller configured to determine a cooling requirement based on the digitized signal from the analog-to-digital converter input;
a Semiconductor cooling driver configured to receive the cooling requirement from the control logic of the microcontroller and regulate current flow; and
a Semiconductor cooling element configured to receive the regulated current flow from the Semiconductor cooling driver and provide thermoelectric cooling to the cooling compartment.

2. The Thermistor and Semiconductor Cooling Control System of claim 1, further comprising a power management circuit configured to generate a plurality of regulated voltage rails including 1.2 volts, 1.4 volts, 1.8 volts, 3.3 volts, and 5 volts to supply the microcontroller, the Semiconductor cooling driver, and at least one communication module.

3. The Thermistor and Semiconductor Cooling Control System of claim 2, wherein the power management circuit is configured to minimize quiescent current to reduce idle battery drain of the thermistor and Semiconductor Cooling Control System.

4. The Thermistor and Semiconductor Cooling Control System of claim 3, further comprising a Bluetooth Low Energy communication module configured to transmit compartment temperature data to a local user device.

5. The Thermistor and Semiconductor Cooling Control System of claim 4, further comprising a Long-Term Evolution communication module configured to transmit telemetry data including compartment temperature and battery voltage to a remote server.

6. The Thermistor and Semiconductor Cooling Control System of claim 5, wherein the control logic of the microcontroller is configured to synchronize operation of the Semiconductor cooling driver with transmission activity of the Bluetooth Low Energy communication module and the Long-Term Evolution communication module to prevent voltage droop on the plurality of regulated voltage rails.

7. The Thermistor and Semiconductor Cooling Control System of claim 6, further comprising a fan and accessory control circuit configured to operate a fan to dissipate heat from a hot side of the Semiconductor cooling element, wherein the fan and accessory control circuit is commanded by the microcontroller.

8. The Thermistor and Semiconductor Cooling Control System of claim 7, further comprising a battery and universal serial bus power input configured to provide input energy to the power management circuit, wherein the battery and universal serial bus power input enables seamless transitions between battery operation and external charging.

9. The Thermistor and Semiconductor Cooling Control System of claim 8, further comprising a safety circuit configured to prevent deep discharge of the battery, manage charging transitions, and ensure stable startup when switching between the battery and the universal serial bus power input.

10. The Thermistor and Semiconductor Cooling Control System of
claim 9, further comprising a cuboidal portable-smart refrigerator assembly including:
a payload assembly defining the cooling compartment; a cooling and printed circuit board assembly including the thermistor and Semiconductor Cooling Control System;
a radiator assembly coupled to the Semiconductor cooling element;
a honeycomb vent enabling airflow across the radiator assembly; and
a lid assembly providing access to the payload assembly.
